(19) United States
(12) Patent Application Publication
(10) Pub. No.: US 2025/0157827 A1
(43) Pub. Date: May 15, 2025

(54) METHOD FOR PRODUCING GLASS SHEET

(71) Applicant: NIPPON ELECTRIC GLASS CO., LTD., Shiga (JP)

(72) Inventor: Hiroaki TANAKA, Shiga (JP)

(21) Appl. No.: 18/838,727

(22) PCT Filed: Jan. 30, 2023
(86) PCT No.: PCT/JP2023/002853

§ 371 Date: Aug. 15, 2024

(30) Foreign Application Priority Data
Feb. 18, 2022 (JP) 2022-023809

(51) Int. Cl. H01L 21/48; C03B 33/02; C03C 15/00

(52) U.S. Cl. CPC H01L 21/486; C03B 33/0222; C03C 15/00

(57) ABSTRACT

Provided is a method of manufacturing a glass sheet, including, after modifying a preset formation part for a through hole by irradiation with laser light, a through hole formation step (S2) of forming a through hole in the preset formation part. The through hole formation step (S2) includes: an etching step (S2a) of etching the t glass sheet with an etchant; and a precipitate removal step (S2b) of removing a precipitate having precipitated in the preset formation part in the etching step (S2a) under a state in which the glass sheet is taken out of the etchant. Thus, the uniformity of the hole diameters of through holes can be improved in a glass substrate.

### TECHNICAL FIELD

The present invention relates to a method of manufacturing a glass sheet having a through hole.

### BACKGROUND ART

A glass sheet having a fine through hole for interconnection (through-via or the like) is used as a substrate of, for example, a tiled display (micro LED or the like), a bezel-less display, or a glass interposer.

A method of manufacturing this type of glass sheet having a through hole includes, for example, a modification step of modifying a preset formation part for the through hole in the glass sheet by irradiation with laser light to form a modified part, and an etching step of etching the preset formation part including the modified part to form a through hole (see, for example, Patent Literatures 1 and 2).

### CITATION LIST

Patent Literature 1: JP 2018-199605 A
Patent Literature 2: JP 2020-66551 A

### SUMMARY OF INVENTION

### Technical Problem

According to the above-mentioned manufacturing method, the modified part formed in the modification step has an etching rate higher than that of a non-modified part, and is hence selectively removed in the etching step. Thus, when the modified part is formed so as to extend from a first main surface to a second main surface along the sheet-thickness direction of the glass sheet, a through hole can be formed by etching.

However, in the above-mentioned manufacturing method, when a reaction product between an etchant and the glass sheet is poorly soluble, the reaction product precipitates in the preset formation part for the through hole in the etching step, and non-uniformly inhibits etching. As a result, for example, there is a problem in that the uniformity of the hole diameters of a plurality of through holes to be finally formed is reduced.

When the uniformity of the hole diameters of the through holes is reduced, it becomes difficult to uniformize the resistance values of a plurality of through-vias in a substrate of, for example, a tiled display, a bezel-less display, or a glass interposer. Accordingly, it is preferred that the uniformity of the hole diameters of the through holes be satisfactory.

An object of the present invention is to improve the uniformity of the hole diameters of through holes in a glass substrate.

### Solution to Problem

(1) According to one embodiment of the present invention, which has been devised in order to achieve the above-mentioned object, there is provided a method of manufacturing a glass sheet having a first main surface, a second main surface, and a through hole that penetrates between the first main surface and the second main the method comprising: surface, a modification step of modifying a preset formation part for the through hole by irradiation with laser light; and a through hole formation step of forming the through hole in the preset formation part after the modification step, wherein the through hole formation step comprises: an etching step of etching the glass sheet with an etchant; and a precipitate removal step of removing a precipitate having precipitated in the etching step under a state in which the glass sheet is taken out of the etchant.

With this configuration, the precipitate can be removed in the precipitate removal step, and hence an influence of the precipitate in the etching step can be significantly suppressed. Accordingly, the uniformity of the hole diameters of the through holes to be formed in the preset formation part can be improved. In addition, the precipitate removal step is performed under the state in which the glass sheet is taken out of the etchant, and hence the precipitate removal step does not adversely affect the etching conditions (e.g., an etching rate) in the etching step.

(2) In the configuration of the above-mentioned item (1), it is preferred that the precipitate removal step comprise removing the precipitate through use of an acid solution.

With this configuration, the precipitate can be removed in a short time period through a reaction between the acid solution and the precipitate.

(3) In the configuration of the above-mentioned item (2), it is preferred that the acid solution contain at least one kind selected from HCl, HNO₃, and H₂SO₄.

A reaction product to be generated through a reaction between each of HCl, HNO₃, and H₂SO₄ and the precipitate has a high solubility. Accordingly, the precipitate can be removed in a shorter time period.

(4) In the configuration of any one of the above-mentioned items (1) to (3), it is preferred that the through hole formation step comprise performing each of the etching step and the precipitate removal step a plurality of times.

With this configuration, after the precipitate has been removed in the precipitate removal step, etching is performed again in the etching step. Accordingly, the uniformity of the hole diameters of the through holes to be formed in the preset formation part can be improved more reliably.

(5) In the configuration of any one of the above-mentioned items (1) to (4), it is preferred that the through hole formation step comprise finally performing the precipitate removal step.

With this configuration, the through hole formation step is completed under the state in which the precipitate in the through hole to be formed in the preset formation part is removed. Accordingly, there is an advantage in that, when the glass sheet having the through hole is washed after the through hole formation step, the washing step can be simplified.

(6) In the configuration of any one of the above-mentioned items (1) to (5), it is preferred that: the etching step comprise a first etching step and a second etching step performed after the first etching step; the precipitate removal step comprise a first precipitate removal step performed between the first etching step and the second etching step; and the first precipitate removal step be started after the preset formation part has penetrated.

Before the preset formation part penetrates, improving effects on the uniformity of the hole diameters of the through holes and their taper angles exhibited by the precipitate removal step are small. When the first precipitate removal step is started after the preset formation part has penetrated, a time period required for the through hole formation step can be shortened while the uniformity of the hole diameters of the through holes to be formed in the preset formation part is improved.

### Advantageous Effects of Invention

According to the present invention, the uniformity of the hole diameters of the through holes in the glass substrate can be improved.

### BRIEF DESCRIPTION OF DRAWINGS

FIG. 1 is a flowchart for illustrating a method of manufacturing a glass sheet according to a first embodiment.

FIG. 2 is a sectional view for illustrating a modification step included in the method of manufacturing a glass sheet according to the first embodiment.

FIG. 3 is a flowchart for illustrating a through hole formation step included in the method of manufacturing a glass sheet according to the first embodiment.

FIG. 4 is a sectional view for illustrating an etching step included in the through hole formation step according to the first embodiment.

FIG. 5 is a sectional view of a glass sheet in the etching step according to the first embodiment, in which the state of the glass sheet before a preset formation part penetrates is illustrated.

FIG. 6 is a sectional view of the glass sheet in the etching step according to the first embodiment, in which the state of the glass sheet when the preset formation part has penetrated is illustrated.

FIG. 7 is a sectional view of the glass sheet having a through hole according to the first embodiment.

FIG. 8 is a main portion enlarged sectional view for has illustrating the glass sheet in which a precipitate precipitated in the preset formation part in the etching step according to the first embodiment.

FIG. 9 is a sectional view for illustrating a precipitate removal step included in the through hole formation step according to the first embodiment.

FIG. 10 is a flowchart for illustrating a through hole formation step included in a method of manufacturing a glass sheet according to a second embodiment,

FIG. 11 is a graph for showing a relationship between an interval between precipitate removal steps and the uniformity of the hole diameters of through holes.

FIG. 12 is a graph for showing a relationship between an interval between precipitate removal steps and the uniformity of the hole diameters of through holes.

FIG. 13 is a graph for showing a relationship between an interval between the precipitate removal steps and the inclination angles (taper angles) of inner wall surfaces of the through holes.

FIG. 14 is a graph for showing a relationship between an interval between the precipitate removal steps and the inclination angles (taper angles) of the inner wall surfaces of the through holes.

FIG. 15 is a graph for showing a relationship between a precipitate removal step start time and the uniformity of the hole diameters of through holes.

FIG. 16 is a graph for showing a relationship between a precipitate removal step start time and the inclination angles (taper angles) of the inner wall surfaces of the through holes.

### DESCRIPTION OF EMBODIMENTS

Embodiments of the present invention are described below with reference to the drawings.

### First Embodiment

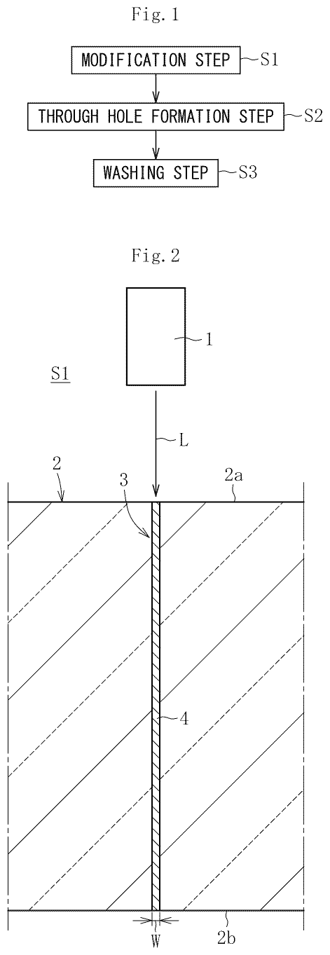

As illustrated in FIG. 1, a method of manufacturing a glass sheet according to a first embodiment comprises a modification step S1, a through hole formation step S2, and a washing step S3 in the stated order.

### Modification Step

As illustrated in FIG. 2, the modification step S1 is a step of modifying a preset formation part 3 for a through hole in a glass sheet 2 with laser light L radiated from a laser device 1. The preset formation part 3 having been modified comprises a modified part 4 extending along a sheet-thickness direction. The modified part 4 has a property of being susceptible to etching and has an etching rate higher than that of a non-modified part. The modified part 4 is preferably formed continuously along the sheet-thickness direction, but may be formed intermittently along the sheet-thickness direction. When a plurality of through holes are formed in the glass sheet 2, a plurality of preset formation parts 3 including the modified part 4 are also formed.

The type and irradiation conditions of the laser light L are not particularly limited as long as the modified part 4 can be formed in the preset formation part 3. In the first embodiment, the laser light L is short-pulse laser light (picosecond laser light, nanosecond laser light, or femtosecond laser light). A diameter W of the modified part 4 may be adjusted by, for example, a spot diameter of the laser light L.

For example, a glass sheet formed of alkali-free glass may be used as the glass sheet 2, and the glass sheet preferably comprises as a glass composition, in terms of mass %, 58% to 68% of SiO₂, 15% to 23% (particularly 17% to 21%) of Al₂O₃, 3% to 9% (particularly 5% to 7%) of B203, 0% to less than 1% (particularly 0% to 0.5%) of Li₂O+Na₂O+K₂O, 1% to 6% (particularly 1% to 4%) of MgO, 3% to 13% (particularly 5% to 10%) of CaO, 0% to 10% (particularly 0.1% to 3%) of Sro, and 0.1% to 5% of BaO. With this configuration, when a thin film is formed on the glass sheet 2, the characteristics of the thin film can be prevented from being impaired. In addition, the glass sheet 2 comprises Ca, Mg, and Ba, and comprises Sr in some cases, and hence a poorly-soluble precipitate is liable to precipitate in an etching step as described later. Accordingly, the effect of the present invention is remarkable.

### (Through Hole Formation Step)

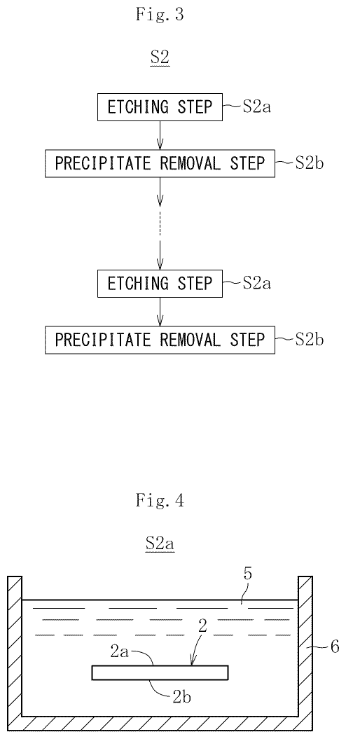

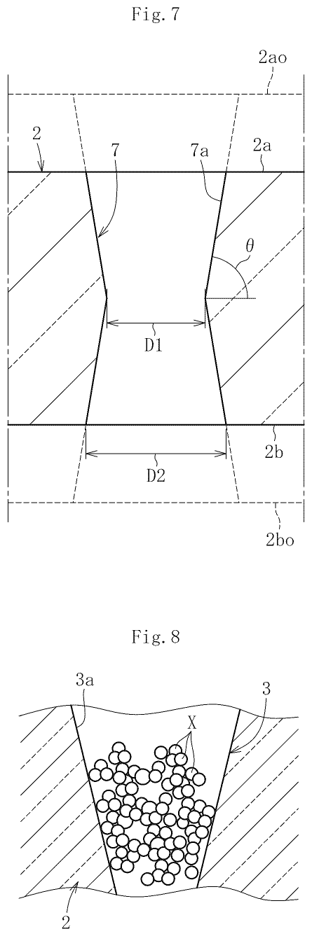

The through hole formation step S2 is a step of forming a through hole 7 (see FIG. 7 described later), which penetrates between a first main surface 2a and a second main surface 2b of the glass sheet 2 in the sheet-thickness direction, in the preset formation part 3 including the modified part 4. As illustrated in FIG. 3, the through hole formation step $2 comprises an etching step S2a and a precipitate removal step S2b. In the first embodiment, the etching step S2a and the precipitate removal step S2b are alternately performed a plurality of times.

As illustrated in FIG. 4, the etching step S2a is a step of etching the glass sheet 2 with an etchant 5.

A HF-based etchant or an alkali-based etchant may be used as the etchant 5. For example, a single acid formed of HF, or a mixed acid of at least one kind of acid selected from HCl, HNO₃, and H₂SO₄ and HF may be used as the HF-based etchant. For example, NaOH or KOH may be used as the alkali-based etchant.

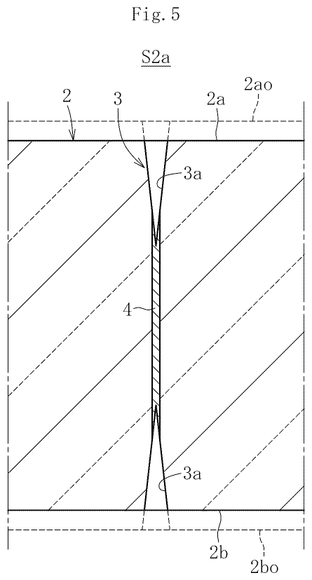

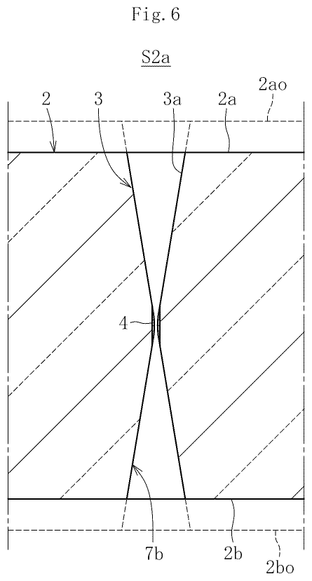

In the first embodiment, in the etching step S2a, the glass sheet 2 is immersed in the etchant 5 stored in an etching bath 6, and etching is advanced simultaneously from both the first main surface 2a side and the second main surface 2b side of the glass sheet 2. The modified part 4 has an etching rate higher than that of the non-modified part, and is hence selectively removed in the etching step S2a. Thus, as illustrated in FIG. 5 and FIG. 6, the preset formation part 3 including the modified part 4 is gradually removed by etching. For example, in an early etching step S2a (first etching step) included in the through hole formation step S2, the preset formation part 3 has not penetrated in the sheet-thickness direction, and forms a bottomed recessed portion (see FIG. 5). After that, in a middle etching step S2a (second or subsequent etching step) included in the through hole formation step S2, the preset formation part 3 penetrates in the sheet-thickness direction, and forms an initial through hole 7b. Then, in a final etching step included in the through hole formation step S2, the through hole 7 as illustrated in FIG. 7 is finally formed with its hole diameter expanded. In each of FIG. 5 to FIG. 7, the positions of the main surfaces 2a and 2b before etching are represented by reference symbols “2ao” and “2bo”, respectively.

However, in the etching step S2a, as illustrated in FIG. 8, a precipitate X precipitates on an inner wall surface 3a of the preset formation part 3 (or an inner wall surface 7a of the through hole 7) in some cases. The precipitate X is a poorly-soluble reaction product (salt) to be generated through a reaction between the etchant 5 and the glass sheet 2, and inhibits the advance of etching. In addition, the precipitate X may precipitate with any size at any position of the inner wall surface 3a of the preset formation part 3. Accordingly, when etching is performed under the state in which the precipitate X precipitates in the preset formation part 3, the degree of the advance of the etching varies among the preset formation parts 3, and hence the uniformity of the hole diameters of the through holes 7 to be finally formed is reduced. Particularly when the glass sheet 2 comprises at least one kind of Ca, Mg, Ba, or Sr in the glass composition, the precipitate X having a low solubility precipitates, and the uniformity of the hole diameters of the through holes 7 is liable to be reduced. In view of the foregoing, in order to improve the uniformity of the hole diameters of the through holes 7, the precipitate removal step S2b of removing the precipitate X having precipitated in the etching step S2a is performed in the manufacturing method of the present invention.

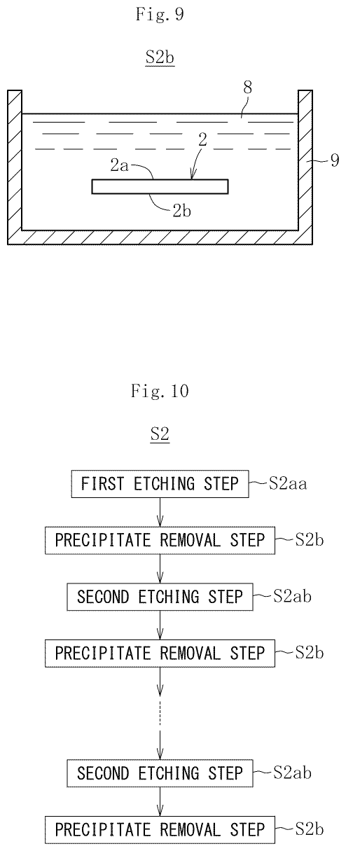

As illustrated in FIG. 9, the precipitate removal step S2b is a step of removing the precipitate X having precipitated in the etching step S2a through use of an acid solution 8 under the state in which the glass sheet 2 is taken out of the etchant 5. In the first embodiment, the glass sheet 2 is immersed in the acid solution 8 stored in a precipitate removal bath 9, which differs from the etching bath 6, and thus the precipitate X having precipitated in a portion including the preset formation part 3 of the glass sheet 2 is removed.

At least one kind of acid selected from HCl, HNO₃, and H₂SO₄ is preferably used as the acid solution 8. A reaction product (salt) to be generated through a reaction between each of HCl, HNO₃, and H₂SO₄ and the precipitate X has a high solubility. Accordingly, the poorly-soluble precipitate X can be efficiently removed in a short time period by being replaced with a soluble reaction product. An acid except for HCl, HNO₃, and H₂SO₄ may also be used as the acid solution 8. A time period for which the precipitate removal step S2b is performed once is, for example, from 1 minute to 5 minutes, but is not limited thereto.

Herein, it is conceivable that when a mixed acid containing the above-mentioned acid solution and HF is used and concurrently the concentration of the acid solution in the mixed acid is increased in the etching step S2a, the generation of the precipitate X in itself is suppressed in the etching step S2a. However, in this case, an inclination angle (taper angle) θ of the inner wall surface 7a of the through hole 7 with respect to a direction perpendicular to the sheet-thickness direction of the glass sheet 2 deteriorates. Accordingly, when the concentration of the acid solution in the mixed acid is set to such a concentration that the inclination angle θ does not deteriorate, a suppressing effect on the generation of the precipitate is insufficient, and hence it is required to perform the precipitate removal step S2b independent of the etching step S2a.

As illustrated in FIG. 3, in the first embodiment, the etching step S2a and the precipitate removal step S2b are alternately performed a plurality of times in the through hole formation step With S2. With this configuration, after the precipitate has been removed in the precipitate removal step S2b, etching is performed again in the etching step S2a. Accordingly, the uniformity of the hole diameters of the through holes 7 to be formed in the preset formation part 3 can be improved more reliably.

An interval between the precipitate removal steps S2b (a time period for which the etching step S2a is performed once) is appropriately adjusted in accordance with the quality of the through holes 7 (uniformity of their hole diameters) to be required. As the interval between the precipitate removal steps S2b becomes shorter, there is a tendency that the uniformity of the hole diameters of the through holes 7 is improved more. The interval between the precipitate removal steps S2b is, for example, preferably 45 minutes or less, more preferably 30 minutes or less, still more preferably 15 minutes or less. The time periods of the respective etching steps S2a may be the same or different from each other. Similarly, the time periods of the respective precipitate removal steps S2b may be the same or different from each other. However, from the viewpoint of properly controlling an etching rate, it is preferred that the time periods of the respective etching steps S2a be the same and the time periods of the respective precipitate removal steps S2b be the same.

In the first embodiment, the final step included in the through hole formation step S2 is set to the precipitate removal step S2b (e.g., etching step S2a-precipitate removal step S2b-etching step S2a-precipitate removal step S2b). That is, the precipitate removal step S2b is necessarily performed after the etching step S2a. With this configuration, the through hole formation step S2 is completed under the state in which the precipitate X in the through hole 7 to be formed in the preset formation part 3 is removed. Accordingly, there is an advantage in that the washing step S3 after the through hole formation step S2 can be simplified. The final step included in the through hole formation step S2 may be the etching step S2a (e.g., etching step S2a-precipitate removal step S2b-etching step S2a).

As described above, the removal of the precipitate X, which has precipitated in the etching step S2a, in the precipitate removal step S2b can prevent a situation in which the precipitate X having precipitated on the inner wall 3a of the preset formation part 3 inhibits etching. Thus, the uniformity of the hole diameters of the through holes 7 formed in the glass sheet 2 can be improved. In addition, a portion closer to each of the main surfaces 2a and 2b of the glass sheet 2 is brought into contact with the etchant 5 for a longer time as period, and is hence etched more easily. Accordingly, illustrated in FIG. 7, the hole diameter of the through hole 7 is larger in the portion closer to each of the main surfaces 2a and 2b than in a center portion in the sheet-thickness direction, and the inner wall surface 7a of the through hole 7 has a tapered shape. However, when the precipitate removal step S2b is performed, the precipitate X, which inhibits the advance of etching in the preset formation part 3, is removed, and hence the preset formation part 3 can be efficiently etched in the etching step S2a. As a result, while the taper angles θ of the through holes 7 are increased, the uniformity of the hole diameters of the through holes 7 is improved. That is, a difference between a hole diameter (minimum diameter) D1 of the through hole 7 in the center portion in the sheet-thickness direction and a hole diameter (maximum diameter) D2 of the through hole 7 on each of the main surfaces 2a and 2b is reduced.

### (Washing Step)

In the washing step S3, although the illustration is omitted, the glass sheet 2 is taken out of the precipitate removal bath 9 or the etching bath 6, and is moved to a washing bath separately prepared. In the washing bath, the glass sheet 2 is washed by being sprayed with a wash solution (e.g., pure water) through a nozzle.

### Second Embodiment

As illustrated in FIG. 10, a method of manufacturing a glass sheet according to a second embodiment differs from the method of manufacturing a glass sheet according to the first embodiment in that the etching step S2a comprises: a first etching step S2aa (first etching step) of forming the initial through hole 7b in the preset formation part 3; and a second etching step S2ab (second etching step) of expanding the hole diameter of the initial through hole 7b to form the through hole 7 having predetermined dimensions, and the first precipitate removal step S2b is started after the completion of the first etching step S2aa (after the initial through hole 7b has been formed).

During performance of the first etching step S2aa, the preset formation part 3 has not penetrated, and forms a bottomed recessed portion. Before the preset formation part 3 penetrates, improving effects on the uniformity of the hole diameters of the through holes 7 and their taper angles exhibited by the precipitate removal step S2b are small. Accordingly, in order to shorten a time period required for the through hole formation step S2, the first precipitate removal step S2b is preferably started when the preset formation part 3 penetrates.

In the second embodiment, a time period from the time when the first etching step S2aa is started to the time when the initial through hole 7b is formed is measured in advance, and when the measured time period has elapsed, the initial through hole 7b is regarded as having been formed, and the precipitate removal step S2b is started. It is also appropriate that the time when the initial through hole 7b is formed be observed with a camera or the like in real time, and at a time point when the formation of the initial through hole 7b is observed, the precipitate removal step S2b be started.

The first precipitate removal step S2b may be started before the preset formation part 3 penetrates (e.g., several minutes before the penetration). Alternatively, the first precipitate removal step S2b may be started after the preset formation part 3 has penetrated (e.g., several minutes after the penetration).

The present invention is not limited to the configurations of the above-mentioned embodiments. In addition, the actions and effects of the present invention are not limited to those described above. The present invention may be modified in various forms within the range not departing from the spirit of the present invention.

In each of the above-mentioned embodiments, at the time of transfer from the etching step S2a to the precipitate removal step S2b, a washing step of washing the etchant 5 adhering to the glass sheet 2 may be performed. In addition, at the time of transfer from the precipitate removal step S2b to the etching step S2a, a washing step of washing the acid solution 8 adhering to the glass sheet 2 may be performed. Those washing steps may each comprise a drying step. With this configuration, changes in concentrations of the etchant 5 and/or the acid solution 8 can be suppressed.

While the case in which etching is performed by immersing the glass sheet 2 in the etchant 5 in the etching step S2a has been given as an example in each of the above-mentioned embodiments, the present invention is not limited thereto. For example, etching may be performed by jetting the etchant 5 to both the main surfaces 2a and 2b of the glass sheet 2. Similarly, while the case in which the precipitate X is removed by immersing the glass sheet 2 in the acid solution 8 in the precipitate removal step S2b has been given as an example in each of the above-mentioned embodiments, the present invention is not limited thereto. For example, the precipitate X may be removed by jetting the acid solution 8 to both the main surfaces 2a and 2b of the glass sheet 2.

While the case in which the precipitate X is removed through chemical treatment with the acid solution 8 in the precipitate removal step S2b has been given as an example in each of the above-mentioned embodiments, the present invention is not limited thereto. For example, the precipitate X may be removed through physical treatment, such as a water flow, ultrasonic washing, or brush washing, or the precipitate X may be removed by combining the chemical treatment and the physical treatment.

While the case in which etching is advanced simultaneously from both the first main surface 2a side and the second main surface 2b side of the glass sheet 2 in the etching step S2a has been given as an example in each of the above-mentioned embodiments, the etching may be advanced from only one of the first main surface 2a side and the second main surface 2b side in the etching step S2a. Also in this case, the uniformity of the hole diameters of the through holes to be finally formed can be improved by removing the precipitate, which has precipitated in the etching step S2a, in the precipitate removal step S2b.

### EXAMPLES

The present invention is described in detail below by way of Examples, but the present invention is not limited to these Examples.

First, a reaction product (precipitate) to be formed in an etching step and its solubility, and a reaction product to be formed through a reaction between the reaction product (precipitate) and an acid solution in a precipitate removal step and its solubility are shown in Table 1 and Table 2. The cases in which a glass sheet comprises as a glass composition Ca and/or Mg are shown in Table 1, and the cases in which a glass sheet comprises as a glass composition Ba and/or Sr are shown in Table 2. In each of the cases, the solubility of the reaction product is a solubility in water at 20° C.

TABLE 1

| | | Glass component | | | |
|---|---|---|---|---|---|
| | | Ca | | Mg | |
| | | Reaction | Solubility | Reaction | Solubility |
| | | product | [g/100 mL] | product | [g/100 mL] |
| Etching | HF- | CaF₂ | 0.0016 | MgF₂ | 0.0073 |
| step | based | | | | |
| | Alkali- | Ca(OH)₂ | 0.173 | Mg(OH)₂ | 0.0013 |
| | based | | | | |
| Precipitate | HCl | CaCl₂ | 74.5 | MgCl₂ | 54.6 |
| removal | HNO₃ | Ca(NO₃)₂ | 121.2 | Mg(NO₃)₂ | 69.5 |
| step | H₂SO₄ | CaSO₄ | 0.24 | MgSO₄ | 33.7 |

TABLE 2

| | | Glass component | | | |
|---|---|---|---|---|---|
| | | Ba | | Sr | |
| | | Reaction | Solubility | Reaction | Solubility |
| | | product | [g/100 mL] | product | [g/100 mL] |
| Etching | HF- | BaF₂ | 0.16 | SrF₂ | 0.0117 |
| step | based | | | | |
| | Alkali- | Ba(OH)₂ | 3.89 | Sr(OH)₂ | 1.77 |
| | based | | | | |
| Precipitate | HCl | BaCl₂ | 35.8 | SrCl₂ | 52.9 |
| removal | HNO₃ | Ba(NO₃)₂ | 9.02 | Sr(NO₃)₂ | 69.5 |
| step | H₂SO₄ | BaSO₄ | 0.00285 | SrSO₄ | 0.0132 |

As shown in Table 1, it is found that when the glass sheet comprising Ca and/or Mg is etched in the etching step, a poorly-soluble reaction product is formed in each of the case of using a HF-based etchant and the case of using an alkali-based etchant. Moreover, it is found that when HCl, HNO₃, or H₂SO₄ is used in the precipitate removal step, the poorly-soluble reaction product formed in the etching step is replaced with a reaction product having a higher solubility. That is, the reaction product precipitated in the etching step can be removed in a short time period.

As shown in Table 2, it is found that when the glass sheet comprising Ba and/or Sr is etched in the etching step, a poorly-soluble reaction product is formed in each of the case of using a HF-based etchant and the case of using an alkali-based etchant. Moreover, it is found that when HCl or HNO₃ is used in the precipitate removal step, the poorly-soluble reaction product formed in the etching step is replaced with a reaction product having a higher solubility. That is, the reaction product precipitated in the etching step can be removed in a short time period. In the case where the glass sheet comprises Ba and/or Sr, when H₂SO₄ is used in the precipitate removal step, the poorly-soluble reaction product formed in the etching step is replaced with a reaction product having a comparable or lower solubility. Accordingly, when the glass sheet comprises Ba and/or Sr, a single acid except for H₂SO₄ (HCl or HNO₃) is preferably used in the precipitate removal step. Alternatively, in the case of using H₂SO₄, a mixed acid with an acid except for H₂SO₄ (HCL or HNO₃) is preferably used.

Next, it was evaluated how the uniformity of the hole diameters of a plurality of through holes to be finally formed and the inclination angles (taper angles) of inner wall surfaces of the through holes changed among the cases in which only an etching step was performed in a through hole formation step (Comparative Examples 1 and 2) and the cases in which an etching step and a precipitate removal step were alternately performed therein (Examples 1 to 9) (Evaluation Test 1). In addition, it was evaluated how the uniformity of the hole diameters of a plurality of through holes to be finally formed and the inclination angles (taper angles) of inner wall surfaces of the through holes changed among the cases in which a time at which a first precipitate removal step was started was changed (Examples 10 to 13 and Comparative Examples 3 and 4) (Evaluation Test 2). In each of Evaluation Test 1 and Evaluation Test 2, an alkali-free glass original sheet having a thickness of 500 μm (product name “OA-11” manufactured by Nippon Electric Glass Co., Ltd.) was used as a glass sheet serving as a sample.

Evaluation Test 1 was performed as described below,
(1) In each of Examples 1 to 9, the dimensions of 16 through holes were measured for one glass sheet serving as a sample, and the uniformity of the hole diameters of the through holes was evaluated by the expression: (maximum hole diameter-minimum hole diameter)/(maximum hole diameter+minimum hole diameter)×100 [%]. In each of Examples of the present invention and Comparative Examples, the diameter of the narrowest portion of a through hole (D1 of FIG. 7) is used as its hole diameter. In addition, the maximum hole diameter is the maximum value of the hole diameters of the 16 through holes measured for the one glass sheet, and the minimum hole diameter is the minimum value of the hole diameters of the 16 through holes measured for the one glass sheet. In each of Comparative Examples 1 and 2, the dimensions of 16 through holes in one glass sheet serving as a sample were measured, and the uniformity of the hole diameters of the through holes was evaluated by the expression: (maximum hole diameter-minimum hole diameter)/(maximum hole diameter+minimum hole diameter)×100 [%].
(2) In each of Examples 1 to 9, the dimensions of 16 through holes were measured for one glass sheet serving as a sample, and the inclination angles (taper angles) of inner wall surfaces of the respective through holes were evaluated. In each of Comparative Examples 1 and 2, the dimensions of 16 through holes in one glass sheet serving as a sample were measured, and the inclination angles (taper angles) of inner wall surfaces of the respective through holes were evaluated.
(3) In each of Examples 1 to 9, the total time period of a plurality of etching steps was set to 90 minutes. In each of Comparative Examples 1 and 2, the time period of an etching step (one etching step) was set to 90 minutes. In each of Examples 1 to 5 and Comparative Example 1, an etchant to be used in the etching step was a mixed acid of 1.5 mol/L HF and 0.2 mol/L HCl. In each of Examples 6 to 9 and Comparative Example 2, an etchant to be used in the etching step was 10.0 mol/L NaOH.
(4) In Examples 1 to 5, a time period for which the precipitate removal step was performed once was set to 3 minutes, and an interval between the precipitate removal steps, that is, a time period for which the etching step was performed once was changed to 45 minutes (Example 1), 30 minutes (Example 2), 15 minutes (Example 3), 9 minutes (Example 4), and 5 minutes (Example 5). An acid solution to be used in the precipitate removal step was HCl. In Examples 6 to 9, a time period for which the precipitate removal step was performed once was set to 5 minutes, and an interval between the precipitate removal steps, that is, a time period for which the etching step was performed once was changed to 180 minutes (Example 6), 120 minutes (Example 7), 60 minutes (Example 8), and 30 minutes (Example 9). An acid solution to be used in the precipitate removal step was 1.0 mol/L HCl.
(5) In each of Examples 1 to 9, the final step in the through hole formation step was the precipitate removal step.

Evaluation Test 2 was performed as described below.
(1) In each of Examples 10 to 13 and Comparative Examples 3 and 4, the dimensions of 16 through holes were measured for one glass sheet serving as a sample, and the uniformity of the hole diameters of the through holes was evaluated by the expression: (maximum hole diameter-minimum hole diameter)/(maximum hole diameter+minimum hole diameter)×100 [%]. In each of Examples of the present invention and Comparative Examples, the diameter of the narrowest portion of a through hole (D1 of FIG. 7) is used as its hole diameter. In addition, the maximum hole diameter is the maximum value of the hole diameters of the 16 through holes measured for the one glass sheet, and the minimum hole diameter is the minimum value of the hole diameters of the 16 through holes measured for the one glass sheet.
(2) In each of Examples 10 to 13 and Comparative Examples 3 and 4, the dimensions of 16 through holes were measured for one glass sheet serving as a sample, and the inclination angles (taper angles) of inner wall surfaces of the respective through holes were evaluated.
(3) In each of Examples 10 to 13 and Comparative Examples 3 and 4, the total time period of a plurality of etching steps was set to 90 minutes, and an etchant to be used in the etching step was a mixed acid of 1.5 mol/L HF and 0.2 mol/L HCl.
(4) In Examples 10 to 13, a time period for which the precipitate removal step was performed once was set to 3 minutes, an interval between the precipitate removal steps was set to 15 minutes, and a time at which the first precipitate removal step was started was set to 60 minutes (Example 10), 45 minutes (Example 11), 30 minutes (Example 12), and 15 minutes (Example 13) after the start of the etching step. In Comparative Examples 3 and 4, a time period for which the precipitate removal step was performed once was set to 3 minutes, an interval between the precipitate removal steps was set to 15 minutes, and a time at which the first precipitate removal step was started was set to 90 minutes (Comparative Example 3) and 75 minutes (Comparative Example 4) after the start of the etching step. That is, in Comparative Example 3, after the etching step had been performed for 90 minutes, the precipitate removal step was performed for 3 minutes, and the through hole formation step was thus completed. An acid solution to be used in the precipitate removal step was 1.0 mol/L HCl.
(5) In each of Examples 10 to 13 and Comparative Examples 3 and 4, the final step in the through hole formation step was the precipitate removal step.

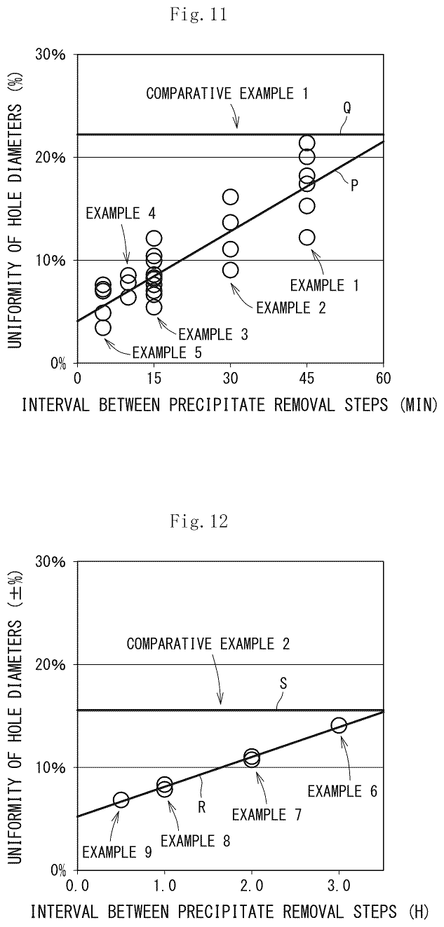

The test results of the uniformity of the hole diameters of the through holes in Evaluation Test 1 described above are shown in FIG. 11 and FIG. 12. In FIG. 11, a line P is an approximate straight line for data of Examples 1 to 5, and a line Q is a straight line that passes data of Comparative Example 1 and is parallel to the abscissa. In FIG. 12, a line R is an approximate straight line for data of Examples 6 to 9, and a line S is a straight line that passes data of Comparative Example 2 and is parallel to the abscissa.

As shown in FIG. 11 and FIG. 12, it can be recognized that the uniformity of the hole diameters of the through holes is improved more in each of Examples 1 to 9, in which the precipitate removal step is performed, than in each of Comparative Examples 1 and 2, in which the precipitate removal step is not performed. In addition, it is found that as the interval between the precipitate removal steps is set to be shorter, the uniformity of the hole diameters of the through holes tends to be more satisfactory.

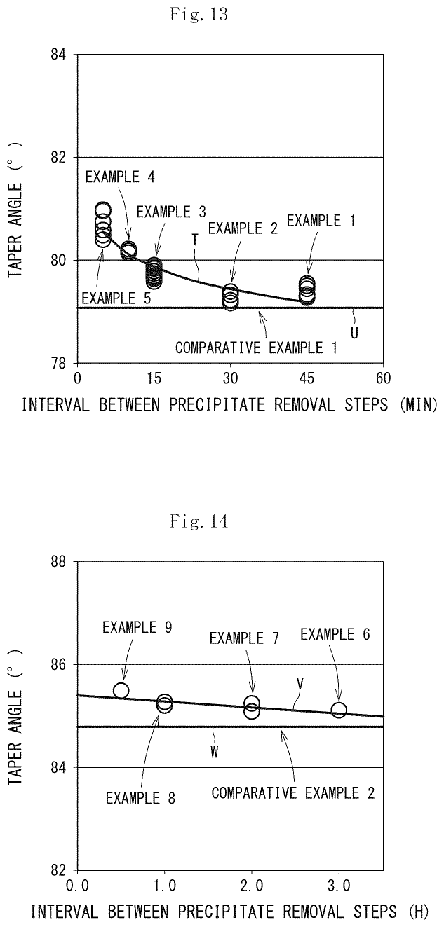

The test results of the inclination angles (taper angles) of inner wall surfaces of the through holes in Evaluation Test 1 described above are shown in FIG. 13 and FIG. 14. In FIG. 13, a line T is an approximate curved line for data of Examples 1 to 5, and a line U is a straight line that passes data of Comparative Example 1 and is parallel to the abscissa. In FIG. 14, a line V is an approximate curved line for data of Examples 6 to 9, and a line W is a straight line that passes data of Comparative Example 2 and is parallel to the abscissa.

As shown in FIG. 13 and FIG. 14, it can be recognized that the inclination angles (taper angles) of inner wall surfaces of the through holes are improved more in each of Examples 1 to 9, in which the precipitate removal step is performed, than in each of Comparative Examples 1 and 2, in which the precipitate removal step is not performed. In addition, it is found that as the interval between the precipitate removal steps is set to be shorter, the inclination angles (taper angles) of inner wall surfaces of the through holes tend to be more satisfactory.

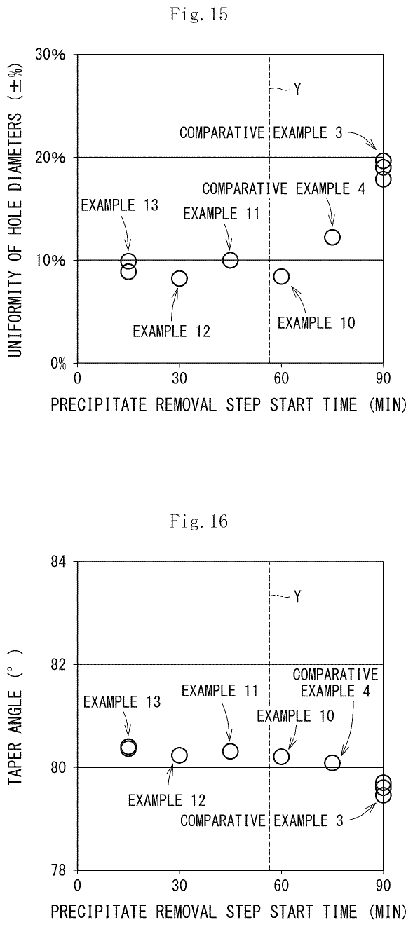

The test results of the uniformity of the hole diameters of the through holes in Evaluation Test 2 described above are shown in FIG. 15. In FIG. 15, a straight line Y is a straight line representing 55 minutes after the start of the through hole formation step, which represents a time at which an initial through hole is formed in the glass sheet.

As shown in FIG. 15, it can be recognized that the uniformity of the hole diameters is improved more in each of Examples 10 to 13, in which the first precipitate removal step is started before the formation of the through holes or within 5 minutes after the formation of the through holes, than in each of Comparative Examples 3 and 4, in which the first precipitate removal step is started after the elapse of a predetermined time period from the formation of the through holes. In addition, it is found that as the time at which the first precipitate removal step is started is set to be earlier so as to be closer to the straight line Y in each of Comparative Examples 3 and 4, the uniformity of the hole diameters of the through holes tends to be more satisfactory. Meanwhile, in Example 10, in which the first precipitate removal step is started within 5 minutes after the formation of the through holes, the uniformity of the hole diameters is satisfactory as in each of Examples 11 to 13, in which the first precipitate removal step is started before the formation of the through holes. Further, in Example 10, a time period required for the through hole formation step can be shortened because the number of times of the precipitate removal steps is smaller than that in each of Examples 11 to 13.

The test results of the inclination angles (taper angles) of inner wall surfaces of the through holes in Evaluation Test 2 described above are shown in FIG. 16. In FIG. 16, a straight line Y is a straight line representing 55 minutes after the start of the through hole formation step, which represents a time at which an initial through hole is formed in the glass sheet.

As shown in FIG. 16, it can be recognized that the inclination angles (taper angles) of inner wall surfaces of the through holes are improved more in each of Examples 10 to 13, in which the first precipitate removal step is started before the formation of the through holes or within 5 minutes after the formation of the through holes, than in each of Comparative Examples 3 and 4, in which the first precipitate removal step is started after the elapse of a predetermined time period from the formation of the through holes. In addition, it is found that as the time at which the first precipitate removal step is started is set to be earlier so as to be closer to the time at which the through holes are formed in each of Comparative Examples 3 and 4, the inclination angles (taper angles) of inner wall surfaces of the through holes tend to be more satisfactory. Meanwhile, in Example 10, in which the first precipitate removal step is started within 5 minutes after the formation of the through holes, the inclination angles (taper angles) of inner wall surfaces of the through holes are satisfactory as in each of Comparative Examples 5 to 7, in which the first precipitate removal step is started before the formation of the through holes. Further, in Example 10, a time period required for the through hole formation step can be shortened because the number of times of the precipitate removal steps is smaller than that in each of Comparative Examples 5 to 7.

### REFERENCE SIGNS LIST

1 laser device
2 glass sheet
2a first main surface
2b second main surface
3 preset formation part
3a inner wall surface
4 modified part
5 etchant
6 etching bath
7 through hole
7a inner wall surface
7b initial through hole
8 acid solution
9 precipitate removal bath
L laser light
S1 modification step
S2 through hole formation step
S2a etching step
S2aa first etching step
S2ab second etching step
S2b precipitate removal step
S3 washing step
θ inclination angle (taper angle) of inner wall surface of through hole

1. A method of manufacturing a glass sheet having a first main surface, a second main surface, and a through hole that penetrates between the first main surface and the second main surface, the method comprising:
a modification step of modifying a preset formation part for the through hole by irradiation with laser light; and
a through hole formation step of forming the through hole in the preset formation part after the modification step,
wherein the through hole formation step comprises:
an etching step of etching the glass sheet with an etchant; and
a precipitate removal step of removing a precipitate having precipitated in the etching step under a state in which the glass sheet is taken out of the etchant.

2. The method of manufacturing a glass sheet according to claim 1, wherein the precipitate removal step comprises removing the precipitate through use of an acid solution.

3. The method of manufacturing a glass sheet according to claim 2, wherein the acid solution contains at least one kind selected from HCl, HNO₃, and H₂SO₄.

4. The method of manufacturing a glass sheet according to claim 1, wherein the through hole formation step comprises performing each of the etching step and the precipitate removal step a plurality of times.

5. The method of manufacturing a glass sheet according to claim 1, wherein the through hole formation step comprises finally performing the precipitate removal step.

6. The method of manufacturing a glass sheet according to claim 1,
wherein the etching step comprises a first etching step and a second etching step performed after the first etching step,
wherein the precipitate removal step comprises a first precipitate removal step performed between the first etching step and the second etching step, and
wherein the first precipitate removal step is started after the preset formation part has penetrated.
